(19) United States
(12) Patent Application Publication
(10) Pub. No.: US 2013/0108963 A1
(43) Pub. Date: May 2, 2013

(54) PHOTOSENSITIVE RESIN COMPOSITION AND METHOD FOR PREPARING PHOTOSENSITIVE COMPOSITION

(71) Applicants: Yuma Tanaka, Shinagawa-ku (JP); Makoto Horii, Shinagawa-ku (JP)

(72) Inventors: Yuma Tanaka, Shinagawa-ku (JP); Makoto Horii, Shinagawa-ku (JP)

(73) Assignee: SUMITOMO BAKELITE CO., LTD., Tokyo (JP)

(21) Appl. No.: 13/701,392

(22) PCT Filed: Jun. 2, 2011
(86) PCT No.: PCT/JP2011/003122

§ 371 Date: Jan. 10, 2013

(30) Foreign Application Priority Data
Jun. 3, 2010 (JP) 2010-127379

(51) Int. Cl. G03F 7/004

(52) U.S. Cl. CPC G03F 7/004
USPC 430/283.1

(57) ABSTRACT

A method for preparing a photosensitive resin composition including at least (A) an alkali-soluble resin, (B) a photoacid generator, (C) a surfactant and (D) an organic solvent includes a step of obtaining a dispersion liquid which contains (C) the surfactant and (D) the organic solvent, and does not contain (A) the alkali-soluble resin and (B) the photoacid generator, and a step of adding (A) the alkali-soluble resin and (B) the photoacid generator to the dispersion liquid.

### TECHNICAL FIELD

The present invention relates to a photosensitive resin composition and a method for preparing a photosensitive resin composition.

### BACKGROUND ART

In the related art, photosensitive resin compositions have been widely used in semiconductor element surface protective films, interlayer insulating films, and manufacturing processes of integrated circuits or printed wiring boards. As the photosensitive resin compositions, polybenzoxazole resins, polyimide resins or the like of which heat resistance is excellent, and having excellent electrical properties, mechanical properties and the like, are used. In addition, combinations of diazoquinone compounds which is a photosensitizer with these polybenzoxazole resins or polyimide resins have also been used as photosensitive resin compositions in order to simplify processes (for example, see Patent Document 1). Furthermore, those in which surfactants are added to photosensitive resin compositions have been used.

In these types of technologies, uniformity of coating properties is achieved by adding a surfactant thereby reducing the surface tension of photosensitive resin compositions. In these technologies, obtaining a photosensitive resin composition by adding a polybenzoxazole resin, a diazoquinone compound which is a photosensitizer and a surfactant all together is a common method.

### RELATED DOCUMENT

### Patent Document

[Patent Document 1] Japanese Laid-open patent publication No. 56-27140

### DISCLOSURE OF THE INVENTION

In the methods for preparing a photosensitive resin composition in the related art, a photosensitive resin composition is obtained by adding a polybenzoxazole resin, a diazoquinone compound which is a photosensitizer and a surfactant all together from the viewpoint of productivity.

However, as a result of studies of the inventors, it is found that the dispersion of a surfactant in a photosensitive resin composition is reduced when the surfactant is added directly to a polybenzoxazole resin. As a result, it is proved that cissing occurred in a film coated on a wafer, and film-coating properties of the photosensitive resin composition is reduced.

The present invention includes the following.

[1]

A method for preparing a photosensitive resin composition including at least (A) an alkali-soluble resin, (B) a photoacid generator, (C) a surfactant and (D) an organic solvent includes a step of obtaining a dispersion liquid which contains (C) the surfactant and (D) the organic solvent, and does not contain (A) the alkali-soluble resin and (B) the photoacid generator, and a step of adding (A) the alkali-soluble resin and (B) the photoacid generator to the dispersion liquid.

[2]

The method for preparing the photosensitive resin composition according to [1], wherein, in the step of obtaining the dispersion liquid, the concentration of (C) the surfactant in the dispersion liquid of the surfactant is less than or equal to a critical micelle concentration.

[3]

The method for preparing the photosensitive resin composition according to [1] or [2], wherein, in the step of obtaining the dispersion liquid, the number of particles with a diameter of 0.15 μm or more is less than or equal to 500/mL.

[4]

The method for preparing the photosensitive resin composition according to any one of [1] to [3], wherein, in the step of obtaining the dispersion liquid, the content of (C) the surfactant with regard to (D) the organic solvent is greater than or equal to 0.005% by mass and less than or equal to 0.5% by mass.

[5]

The method for preparing the photosensitive resin composition according to any one of [1] to [4], wherein, in the step of adding (A) the alkali-soluble resin and (B) the photoacid generator, (D) the organic solvent is further added to the dispersion liquid.

[6]

The method for preparing the photosensitive resin composition according to any one of [1] to [5], wherein (C) the surfactant has a perfluoroalkyl group.

[7]

The method for preparing the photosensitive resin composition according to any one of [1] to [6], wherein (A) the alkali-soluble resin has at least a structure represented by following General Formula (1),

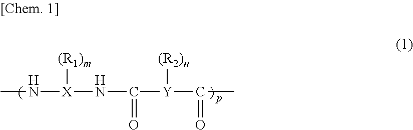

(X represents an organic group having a cyclic structure. R₁ is a hydroxyl group or a —O—R₃, m is an integer of 0 to 2, and these may be the same as or different from each other. Y represents an organic group having a cyclic structure. R₂ is a hydroxyl group, a carboxyl group, a —O—R₃, or a —COO—R₃, n is an integer of 0 to 4, and these may be the same as or different from each other. Here, R₃ is an organic group having 1 to 15 carbon atoms. However, at least one of R₂ should be a carboxyl group when there are no hydroxyl groups as R₁. In addition, at least one of R₁ should be a hydroxyl group when there are no carboxyl groups as R₂. p is an integer of 2 to 300. Here, an organic group having a cyclic structure is, for example, an organic group having an aromatic ring such as a benzene ring, or a naphthalene ring, or an organic group having a heterocyclic ring such as a bisphenol ring, a pyrrole ring or a furan ring.)

A photosensitive resin composition obtained using the method for preparing the photosensitive resin composition according to any one of [1] to [7].

[9]

The photosensitive resin composition according to [8], wherein the number of defects occurring when the photosensitive resin composition is coated on a wafer measured under the following conditions is 50 pcs or less.

### <Condition>

After the photosensitive resin composition is coated on a 6 inch silicon wafer and dried for 3 minutes at 120° C., cissing is observed by microscopy and the number of defects due to cissing per five sheets of wafers is measured.

According to the present invention, a photosensitive resin composition having excellent film-coating properties can be prepared.

### DESCRIPTION OF EMBODIMENTS

The present invention provides a method for preparing a photosensitive resin composition including at least (A) an alkali-soluble resin, (B) a photoacid generator, (C) a surfactant, and (D) an organic solvent. A method for preparing a photosensitive resin composition includes a step of obtaining a dispersion liquid which contains (C) the surfactant and (D) the organic solvent, and does not contain (A) the alkali-soluble resin and (B) the photoacid generator (hereinafter the step of obtaining a dispersion liquid is referred to as a first step), and a step of adding (A) the alkali-soluble resin and (B) the photoacid generator to the dispersion liquid (hereinafter, the step of adding is referred to as a second step).

Next, the method for preparing the photosensitive resin composition of the present invention will be described.

First, the first step is described. The first step is a step of obtaining a dispersion liquid of (C) the surfactant by dispersing (C) the surfactant in (D) the organic solvent. In the first step, it is preferable that, as the dispersion liquid, only (C) the surfactant is dispersed in (D) the organic solvent. In other words, it is most preferable that the components composing the photosensitive resin composition other than (C) the surfactant, for example, (A) the alkali-soluble resin, (B) the photoacid generator and additives (excluding (C) the surfactant) are not added to (D) the organic solvent.

As the method for obtaining a dispersion liquid of (C) the surfactant, for example, a dispersion method using a shear force generated when a stirring blade is rotated is used. In the present invention, it is preferable that dispersion can be carried out by stirring for several minutes to several hours at 200 to 300 rpm using a stirrer with stirring blades. In the first step, the degree of dispersion of (C) the surfactant in the dispersion liquid may be controlled by appropriately selecting a stirrer, stirring time, the number of revolutions, and the like.

In addition, it is more preferable that the dispersion be carried out by adjusting the concentration of (C) the surfactant with respect to (D) the organic solvent (sometimes referred to as a surfactant concentration) to be a critical micelle concentration or less. Here, by setting the surfactant concentration at a critical micelle concentration or less, likelihood of the occurrence of surfactant lumps with the micelle as a core may be suppressed. Therefore, the occurrence of cissing due to the surfactant lumps when the photosensitive resin composition is spin-coated on a wafer may be suppressed.

In addition, the critical micelle concentration is a surfactant concentration at a time when there is no decrease in the surface tension of the liquid when the addition amount of the surfactant to the liquid is gradually increased. Generally, the formation of micelles in the liquid begins when the surfactant concentration in the liquid exceeds a critical micelle concentration. Here, the micelle is aggregates in which molecules with a portion having an affinity for oil and with a portion having an affinity for water such as a surfactant are gathered in a spherical form with a portion having an affinity for oil as the inside in water.

Furthermore, in the first step, the content of (C) the surfactant is preferably greater than or equal to 0.005% by mass and less than or equal to 1.0% by mass, and more preferably greater than or equal to 0.01% by mass and less than or equal to 0.5% by mass with regard to the total amount, 100% by mass, of (D) the organic solvent. By setting the content of (C) the surfactant in the dispersion liquid within the above range, the dispersion liquid with excellent dispersion properties of (C) the surfactant may be obtained. In order to improve the dispersion properties of (C) the surfactant, the number of revolutions may be increased or a stirring time may be extended.

In the dispersion liquid obtained using the dispersion method described above, the number of particles in the liquid with a diameter of 0.15 μm or more is preferably 500/mL or less, and more preferably 400/mL or less. By setting the number of particles in the liquid within the above range, (C) the surfactant is fully dispersed.

Here, as a result of studies the inventors carried out, it has been proved that the number of particles in the liquid with a diameter of 0.15 μm or more in the dispersion liquid of the surfactant represents dispersibility of (C) the surfactant. The number of particles in the liquid may be calculated using, for example, a particle-in-liquid measuring device KS-41 (manufactured by RION Co., Ltd.). Next, the fact that the number of particles in the dispersion liquid represents the dispersion property of (C) the surfactant is described. First, after (C) the surfactant and (D) the organic solvent are mixed, (C) the surfactant is dispersed in (D) the organic solvent while stirring. Sampling is carried out at regular intervals. For each sample, the particles in the liquid with a diameter of 0.15 μm or more are measured. As a result, it has been proved that the amount of the particles in the dispersion liquid decreased with dispersion time by stirring. From the above experimental result, the number of particles in the dispersion liquid has been proved to represent dispersibility of (C) the surfactant. Furthermore, it has been found that the number of particles in the dispersion liquid being 500/mL or less represents a state in which (C) the surfactant is sufficiently dispersed.

Next, the second step is described. The second step is a step subsequently performed after the first step. For example, at least (A) the alkali-soluble resin and (B) the photoacid generator are added to the dispersion liquid in which (C) the surfactant is dispersed obtained in the first step (hereinafter sometimes referred to as dispersion liquid of (C) the surfactant). After that, the dispersion liquid in which these are added is mixed, and the photosensitive resin composition in which (A) the alkali-soluble resin, (B) the photoacid generator and (C) the surfactant are dissolved or dispersed in (D) the organic solvent is obtained.

In the second step, an addition order or an addition aspect of the components composing the photosensitive resin composition excluding (C) the surfactant (hereinafter sometimes referred to as components other than (C) the surfactant) is not particularly limited. For example, each of the components other than (C) the surfactant may be added sequentially, or the components other than (C) the surfactant may be mixed in advance and then added to the dispersion liquid of (C) the surfactant. In addition, an addition order of the components other than (C) the surfactant is not particularly limited. For example, (A) the alkali-soluble resin, (B) the photoacid generator and other additives may be added to the dispersion liquid of (C) the surfactant in this order, or in the order of (B) the photoacid generator, (A) the alkali-soluble resin and other additives. Meanwhile, a mixture of (A) the alkali-soluble resin and (B) the photoacid generator mixed in advance, or a mixture of (A) the alkali-soluble resin, (B) the photoacid generator and other additives may be added to the dispersion liquid of (C) the surfactant. When a mixture is prepared in advance as described above, this preparation may be carried out prior to the first step or after the first step. Here, the other additives may be, although being described later, for example, (D) the organic solvent.

In the second step, a method of dissolving or dispersing (A) the alkali-soluble resin and (B) the photoacid generator in the dispersion liquid of (C) the surfactant is not particularly limited and, for example, includes a stirring method, or the like. In addition, in the second step, (A) the alkali-soluble resin and (B) the photoacid generator may be dissolved or dispersed by appropriately selecting a stirrer, a stirring time, a stirring temperature, and the like.

As a result of the above, the photosensitive resin composition of the present invention is obtained.

In the present invention, a dispersion liquid in which (C) the surfactant is dispersed in (D) the organic solvent in advance is obtained. Therefore, (C) the surfactant can be sufficiently dispersed. Thus, the occurrence of lumps of (C) the surfactant or the increase of solution viscosity of the photosensitive resin composition can be suppressed. As a result, the occurrence of cissing on a film coated with the photosensitive resin composition can be suppressed, and therefore the film-coating properties of the photosensitive resin composition can be improved.

Furthermore, according to the present invention, dispersion of (C) the surfactant in the photosensitive resin composition is facilitated, and a method for preparing a photosensitive resin composition with few defects due to cissing can be provided.

In addition, in the present invention, a resin composition with photosensitivity in which at least (A) the alkali-soluble resin, (B) the photoacid generator and (C) the surfactant are dispersed in (D) the organic solvent can be provided. This photosensitive resin composition is made to be, for example, a positive type.

Obtaining a positive pattern using a positive-type photosensitive resin composition is described. First, a positive-type photosensitive resin composition contains (A) the alkali-soluble resin and (B) the photoacid generator. Before an exposure, alkali solubility of (A) the alkali-soluble resin is reduced. Through the exposure, (B) the photoacid generator generates an acid. The alkali solubility of (A) the alkali-soluble resin increases by an action of this acid. Therefore, the alkali solubility of the positive-type photosensitive resin composition itself increases. The alkali solubility of the unexposed portion decreases and on the contrary the alkali solubility of the exposed portion increases due to a selective exposure. By taking advantage of such properties, a positive-type pattern is obtained by a selective exposure and an alkali development.

Next, the components of the photosensitive resin composition of the present invention will be described.

(A) the alkali-soluble resin is not particularly limited as long as it is alkali developable in an alkali developing liquid, but it may include, for example, an acrylic-based resin such as a cresol-type novolak resin, a hydroxystyrene resin, a methacrylic acid resin or a methacrylate ester resin, a cyclic olefin-based resin including a hydroxyl group, a carboxyl group or the like, a polyamide-based resin, or the like.

As (A) the alkali-soluble resin, a polyamide-based resin is preferable among these. Specifically, a resin having at least one of a polybenzoxazole structure and a polyimide structure, and having a hydroxyl group, a carboxyl group, an ether group or an ester group in the main chain or the side chain, a resin having a polybenzoxazole precursor structure, a resin having a polyimide precursor structure, a resin having a polyamic acid ester structure, or the like, may be included.

Examples of the polyamide-based resin regarding (A) the alkali-soluble resin (A) may include a polyamide-based resin including a structure represented by following General Formula (1)

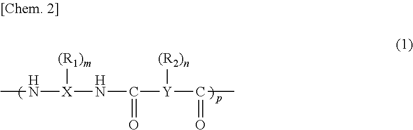

In General Formula (1) above, X represents an organic group having a cyclic structure. R₁ is a hydroxyl group or a —O—R₃, m is an integer of 0 to 2, and these may be the same as or different from each other.

Y represents an organic group having a cyclic structure. R₂ is a hydroxyl group, a carboxyl group, a —O—R₃, or a —COO—R₃, n is an integer of 0 to 4, and these may be the same as or different from each other. Here, R₃ is an organic group having 1 to 15 carbon atoms. However, at least one of R₂ should be a carboxyl group when there are no hydroxyl groups as R₁. In addition, at least one of R₁ should be a hydroxyl group when there are no carboxyl groups as R₂. p is an integer of 2 to 300.

Here, an organic group having a cyclic structure is, for example, an organic group having an aromatic ring such as a benzene ring or a naphthalene ring, or an organic group having a heterocyclic ring such as a bisphenol ring, a pyrrole ring or a furan ring.

The polyamide-based resin including the structure represented by General Formula (1) is obtained, for example, from the reaction of a compound selected from diamines, bis(aminophenols), diaminophenols or the like having a structure of X, and a compound selected from tetracarboxylic anhydride, trimellitic anhydride, dicarboxylic acid or dicarboxylate dichloride, dicarboxylic acid derivatives, hydroxydicarboxylic acid, hydroxydicarboxylic acid derivatives or the like having a structure of Y. In addition, in the case of dicarboxylic acid, an active ester type dicarboxylic acid derivative with which 1-hydroxy-1,2,3-benzotriazole or the like is reacted in advance may be used in order to increase the reaction yield, and the like.

A heat-resistant resin may be obtained in the form of polyimide, polybenzoxazole, or a copolymer of the two by cyclodehydration when a polyamide resin including the structure represented by General Formula (1) is, for example, heated at 300 to 400° C.

In addition, X in above Formula (1) is an organic group having an aromatic ring or an organic group having a heterocyclic ring.

The organic group having an aromatic ring is, for example, an organic group having an aromatic ring such as a benzene ring or a naphthalene ring. More specifically, examples of the organic group having an aromatic ring may include an organic group represented by an organic group having a phenyl group, a naphthyl group, a 2,2′-diphenyl propane skeleton, an organic group having a hexafluoro-2,2′-diphenylpropane skeleton, an organic group having a diphenyl ether skeleton or an organic group having a diphenyl thio ether skeleton, or the like. Furthermore, an organic group in which a plurality of aromatic rings are bonded through —O—, an alkylene group (for example, —CH₂— or the like), —C(CF₃)₂—, —SO₂, —S—, —CO—, —NH— or the like may also be included.

In addition, the organic group having a heterocyclic ring may be, for example, an organic group having a heterocyclic ring such as a pyrrole ring or a furan ring.

(B) The photoacid generator used in the present invention is a compound generating an acid by being irradiated with visible light or ultraviolet light, prefearbly radiation having the wavelength of 200 to 500 μm, thereby increasing the solubility of the photosensitive resin composition in an alkali developing liquid. (B) The photoacid generator is not limited as long as it is a compound including quinone diazide.

Specifically, 1,2-benzoquinonediazide-4-sulfonate, 1,2-naphthoquinonediazide-4-sulfonate, 1,2-naphthoquinonediazide-5-sulfonate, or the like, may be included.

Examples of (C) the surfactant may include nonionic-based surfactants such as polyoxyethylene alkyl ethers such as polyoxyethylene lauryl ether, polyoxyethylene stearyl ether or polyoxyethylene oleyl ether, polyoxyethylene aryl ethers such as polyoxyethylene octylphenyl ether or polyoxyethylene nonylphenyl ether, polyoxyethylene dialkyl esters such as polyoxyethylene dilaurate or polyoxyethylene distearate, fluorine-based surfactants which are commercially available under names such as F-Top EF301, F-Top EF303, F-Top EF352 (manufactured by Shin Akita Kasei Co., Ltd.), Megaface F171, Megaface F172, Megaface F173, Megaface F177, Megaface F444, Megaface F470, Megaface F471, Megaface F475, Megaface F482, Megaface F477 (manufactured by DIC Corporation), Fluorad FC-430, Fluorad FC-431, Novec FC4430, Novec FC4432 (manufactured by Sumitomo 3M Limited), Surflon S-381, Surflon S-382, Surflon S-383, Surflon S-393, Surflon SC-101, SurflonSC-102, SurflonSC-103, Surflon SC-104, Surflon SC-105 or Surflon SC-106 (manufactured by AGC Seimi Chemical Co., Ltd.), organosiloxane polymer KP341 (manufactured by Shin-Etsu Chemical Co., Ltd.), Polyflow No. 57 and 95 which are (meth)acrylic acid-based copolymers (manufactured by Kyoeisha Chemical Co., Ltd.), or the like. Fluorine-based surfactants are preferable among these surfactants.

Among the fluorine-based surfactants, a surfactant having a perfluoroalkyl group is particularly preferably effective.

Specifically, Megaface F171, Megaface F173, Megaface F444, Megaface F470, Megaface F471, Megaface F475, Megaface F482, Megaface F477 (manufactured by DIC Corporation), Surflon S-381, Surflon S-383, Surflon S-393 (manufactured by AGC Seimi Chemical Co., Ltd.), Novec FC4430, Novec FC4432 (manufactured by Sumitomo 3M Limited), or the like, may be included.

As (D) the organic solvent, an organic solvent providing favorable solubility for (A) the alkali-soluble resin may be used. Examples of (D) the organic solvent may include N-methyl-2-pyrrolidone, γ-butyrolactone, N,N-dimethylacetamide, dimethyl sulfoxide, diethylene glycol dimethyl ether, diethylene glycol diethyl ether, diethylene glycol dibutyl ether, propylene glycol monomethyl ether, dipropylene glycol monomethyl ether, propylene glycol monomethyl ether acetate, methyl lactate, ethyl lactate, butyl lactate, methyl-1,3-butylene glycol acetate, 1,3-butylene glycol-3-monomethyl ether, methyl pyruvate, ethyl pyruvate, methyl-3-methoxypropionate, or the like. These organic solvents may be used either alone or as a mixture.

In addition, if necessary, the photosensitive resin composition may contain other additives such as a leveling agent or a silane coupling agent.

### EXAMPLES

Hereinafter, the present invention will be described in detail, however, the present invention is not limited to these examples.

### Example 1

### <Synthesis of (A) Alkali-Soluble Resin>

492.5 parts by weight (1 mol) of a dicarboxylic acid derivative obtained by reacting 1 mol of diphenylether-4,4′-dicarboxylic acid and 2 moles of 1-hydroxybenzotriazole and 403.0 parts by weight (1.10 mol) of hexafluoro-2,2-bis(3-amino-4-hydroxyphenyl)propane were added to a four-necked separable flask equipped with a thermometer, a stirrer, a raw material inlet, and a dry nitrogen gas inlet tube and were dissolved by adding 3,000 parts by weight of N-methyl-2-pyrrolidone. After that, the mixture was reacted for 18 hours at 75° C. using an oil bath.

Next, after the reaction mixture was filtered, the reaction mixture was poured into a solution of water/isopropyl alcohol=3/1, the precipitate was collected by filtration and washed thoroughly with water, and dried under vacuum, obtaining a polyamide resin which is (A) the alkali-soluble resin having a repeating unit of Formula (A-1) (it becomes a polybenzoxazole resin by cyclodehydration when heated at 300 to 400° C.).

### <Preparation of Positive-Type Photosensitive Resin Composition>

0.15 parts by weight of Surfactant A (Megaface F477, manufactured by DIC Corporation) having a perfluoroalkyl group in which a critical micelle concentration in γ-butyrolactone is 4000 ppm, and 150 parts by weight of γ-butyrolactone were stirred for 1 hour at 300 rpm in a stirrer with stirring blades, and a dispersion liquid was obtained by dispersing the Surfactant A in the γ-butyrolactone (the first step). Next, after 100 parts by weight of the alkali-soluble resin including a structure represented by following Formula (A-1) and 15 parts by weight of the photoacid generator of following Formula (B-1) were sequentially added to the dispersion liquid, the mixture was stirred further for 1 hour or more, and a photosensitive resin composition was obtained (the second step).

After the filtrate of the positive-type photosensitive resin composition obtained was coated on a wafer using a spin coater, it was dried for 4 minutes at 120° C. using a hot plate, and a coated film with a thickness of approximately 7 μm was obtained.

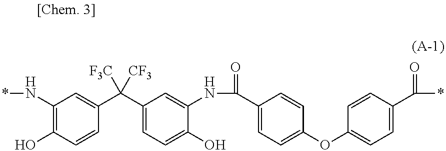

(Repetition number (p) represents an integer of 2 to 300, and * represents bonding locations)

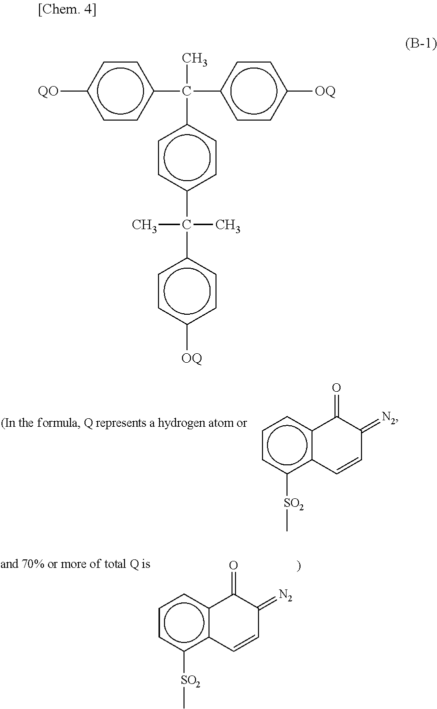

The following evaluations were performed on the dispersion liquid of (C) the surfactant and the photosensitive resin composition obtained in Example 1. The evaluation results are shown in Table 1.

### <Property Evaluation>

### [Degree of Dispersion]

In the first step, after stirring for a predetermined time, the number of particles (number/mL) in the dispersion liquid with a diameter of 0.15 μm or more was measured using a particle-in-liquid measuring device KS-41 (manufactured by RION Co., Ltd.), and the number was defined as the degree of dispersion of (C) the surfactant.

### [Cissing]

Cissing on the coated film was observed by microscopy, and the number of defects (pcs) due to cissing per five sheets of wafers was measured.

Cissing is a phenomenon in which shrinkage occurs in a circle or an ellipse shape around the lumps of the surfactant on a coated film, and then pinholes with diameters of tens of μm to hundreds of μm occur. The measurement conditions for the number of defects due to the wafer: After 2 g of the photosensitive resin composition was added onto the 6 inch silicon wafer coated at 2300 rpm, and dried for 3 minutes at 120° C., and then cissing of the photosensitive resin composition was observed using an optical microscope.

### [Coating Property Evaluation]

Coating properties of the coated film were observed using the evaluation of the cissing described above, and a number of defects due to cissing of 20 pcs or less was determined as favorable, of 50 pcs or less as slightly favorable, and of greater than 50 pcs as poor.

In Example 1, the number of particles in the liquid was 400/mL or less. In addition, the cissing of the coated film was 20 pcs or less. The coating properties of the photosensitive resin composition obtained in Example 1 were also favorable. Furthermore, in Example 1, even when the order of addition of (A) the alkali-soluble resin and (B) the photoacid generator was switched, the film-coating properties were also favorable.

### Example 2

0.15 parts by weight of Surfactant B (Megaface F444, manufactured by DIC Corporation) having a perfluoroalkyl group in which a critical micelle concentration in γ-butyrolactone is 5%, and 150 parts by weight of γ-butyrolactone were stirred for 1 hour at a rotational speed of 300 rpm in a stirrer with stirring blades, and then a dispersion liquid was obtained by dispersing the Surfactant B in the γ-butyrolactone (the first step). Next, after 100 parts by weight of the alkali-soluble resin of following Formula (A-1) and parts by weight of the photoacid generator of following Formula (B-1) were sequentially added to the dispersion liquid, the mixture was stirred further for 1 hour or more, and a photosensitive resin composition was obtained (the second step).

After the filtrate of the positive-type photosensitive resin composition obtained was coated on a wafer using a spin coater, it was dried for 4 minutes at 120° C. using a hot plate, and a coated film with a thickness of approximately 7 μm was obtained.

The number of particles in the liquid with a diameter of 0.15 μm or more, cissing, and coating properties were evaluated in the same manner as that of Example 1. The evaluation results are shown in Table 1. In Example 2, the number of particles in the liquid was 500/mL or less. In addition, the cissing of the coated film was 20 pcs or less. Furthermore, the coating properties were favorable.

### Example 3

0.15 parts by weight of Surfactant A (Megaface F477, manufactured by DIC Corporation) and 150 parts by weight of γ-butyrolactone were stirred for 2 hours at 300 rpm in a stirrer with stirring blades, and a dispersion liquid was obtained by dispersing the Surfactant A in the γ-butyrolactone (the first step). Next, after 100 parts by weight of the alkali-soluble resin of following Formula (A-1) and 15 parts by weight of the photoacid generator of following Formula (B-1) were added to the dispersion liquid, the mixture was stirred further for 1 hour or more, and a photosensitive resin composition was obtained (the second step).

After the filtrate of the positive-type photosensitive resin composition obtained was coated on a wafer using a spin coater, it was dried for 4 minutes at 120° C. using a hot plate, and a coated film with a thickness of approximately 7 μm was obtained.

The number of particles in the liquid with a diameter of 0.15 μm or more, cissing, and coating properties were evaluated in the same manner as that of Example 1. The evaluation results are shown in Table 1. In Example 3, the number of particles in the liquid was 500/mL or less, and therefore, was favorable. In addition, the cissing of the coated film was 20 pcs or less. Furthermore, the coating properties were favorable.

### Example 4

0.15 parts by weight of Surfactant A (Megaface F477, manufactured by DIC Corporation) and 50 parts by weight of γ-butyrolactone were stirred for 1 hour at a rotational speed of 300 rpm in a stirrer with stirring blades, and then a dispersion liquid was obtained by dispersing the Surfactant A in the γ-butyrolactone (the first step). Next, after a mixture of 100 parts by weight of the alkali-soluble resin of following Formula (A-1), 15 parts by weight of the photoacid generator of following Formula (B-1) and 100 parts by weight of γ-butyrolactone was added to the dispersion liquid, the mixture was stirred further for 1 hour or more, and a photosensitive resin composition was obtained (the second step).

After the filtrate of the positive-type photosensitive resin composition obtained was coated on a wafer using a spin coater, it was dried for 4 minutes at 120° C. using a hot plate, and a coated film with a thickness of approximately 7 μm was obtained.

The number of particles in the liquid with a diameter of 0.15 μm or more, cissing, and coating properties were evaluated in the same manner as that of Example 1. The evaluation results are shown in Table 1. In Example 4, the number of particles in the liquid became 500/mL or less, and therefore, was favorable. In addition, the cissing of the coated film was 20 pcs or less. The coating properties were also favorable. Furthermore, in Example 4, when (A) the alkali-soluble resin, (B) the photoacid generator, and (D) the organic solvent were sequentially added, the film-coating properties were also favorable.

### Example 5

### <Synthesis of (A) Alkali-Soluble Resin>

30.0 g (0.082 mol) of 2,2-bis(3-amino-4-hydroxyphenyl)hexafluoropropane and 400 mL of acetone were placed in a 500 mL round bottom flask and were stirred until 2,2-bis(3-amino-4-hydroxyphenyl)hexafluoropropane was dissolved. 12.4 g (0.18 mol) of para-nitrobenzoyl chloride dissolved in 100 mL of acetone was added dropwise thereto over 30 minutes while cooling so that the temperature was 20° C. or less, and a mixture was obtained. After the dropwise addition, the mixture was heated at 40° C. and stirred for 2 hours. 30.0 g (0.218 mol) of potassium carbonate was slowly added thereto and the mixture was stirred further for 2 hours. The heating was stopped and the mixture was stirred further for 18 hours at a room temperature. After that, an aqueous solution of sodium hydroxide was slowly added while vigorously stirring the mixture, and the mixture was heated to 55° C. after the addition and was stirred further for 30 minutes. After the stirring was complete, the resultant was cooled down to the room temperature, 37% by weight aqueous hydrochloric acid and 500 mL of water were added so that the pH was adjusted to be in the range of 6.0 to 7.0. The precipitate was separated by filtration, washed with water, and then was dried at 60 to 70° C., resulting in a solid of bis-N,N′-(para-nitrobenzoyl)hexafluoro-2,2-bis(4-hydroxyphenyl)propane. 316 g of acetone and 158 g of methanol were added to 51.0 g of the solid obtained and the solid was completely dissolved by heating the mixture at 50° C. 300 mL of pure water at 50° C. was added over 30 minutes thereto, and the mixture was heated up to 65° C. After that, the mixture was cooled down slowly to the room temperature, the precipitated crystals were filtered, and then purified by drying the crystals at 70° C., resulting in bis-N,N′-(para-nitrobenzoyl)hexafluoro-2,2-bis(4-hydroxyphenyl)propane.

20 g of the bis-N,N′-(para-nitrobenzoyl)hexafluoro-2,2-bis(4-hydroxyphenyl)propane obtained was placed in a 1 L flask, and was made to be a suspension by adding 1.0 g of 5% palladium-carbon and 180.4 g of ethyl acetate. Hydrogen gas was purged thereto, the mixture was shaken for 35 minutes while heating at 50 to 55° C. and was subjected to a reduction. After the reaction was completed, the resultant was cooled down to 35° C. and the suspension was purged with nitrogen. After the catalyst was removed by filtration, the filtrate was applied to an evaporator and the solvent was evaporated. The product obtained was dried at 90° C., and bis-N,N′-(para-aminobenzoyl)hexafluoro-2,2-bis(4-hydroxyphenyl)propane was obtained.

14.27 parts by weight (0.024 mol) of bis-N,N′-(para-aminobenzoyl)hexafluoro-2,2-bis(4-hydroxyphenyl)propane and 40 parts by weight of γ-butyrolactone were placed in a 300 mL flask and were cooled down to 15° C. while stirring. 6.86 parts by weight (0.022 mol) of 4,4′-oxydiphthalic anhydride and 12.0 parts by weight of γ-butyrolactone were added thereto and the mixture was stirred for 1.5 hours at 20° C. After the mixture was heated up to 50° C. and then stirred for 3 hours, 5.27 g (0.044 mol) of N,N-dimethylformamide dimethyl acetal and 10.0 g of γ-butyrolactone were added thereto and the mixture was stirred further for 1 hour at 50° C. After the reaction was complete, the mixture was cooled down to the room temperature, the reaction mixture was filtered, and then the reaction mixture was poured into a solution of water/isopropyl alcohol=3/1. The precipitate was collected by filtration, washed thoroughly with water, and dried under vacuum, resulting in a polyamide resin which is (A) the alkali-soluble resin having a repeating unit of General Formula (A-2) (a resin becoming a polybenzoxazole resin by cyclodehydration when heated at 300 to 400° C.).

The photosensitive resin composition and a coated film thereof were prepared in the same manner as that of Example 1 except that the alkali-soluble resin including a structure represented by following Formula (A-2) was used instead of the alkali-soluble resin (A-1) used in Example 1.

The number of particles in the liquid with a diameter of 0.15 μm or more, cissing, and coating properties were evaluated in the same manner as that of Example 1. The evaluation results are shown in Table 1. In Example 5, the number of particles in the liquid became 500/mL or less, and therefore, was favorable. In addition, the cissing of the coated film was 20 pcs or less. Furthermore, the coating properties were favorable.

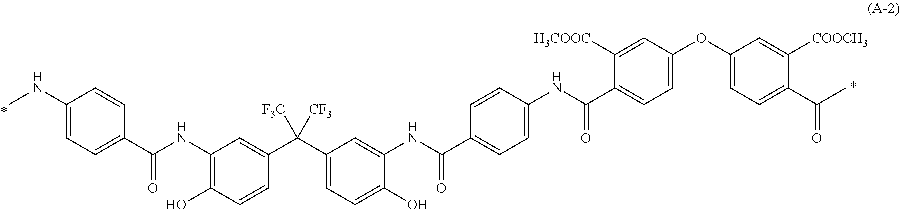

(Repetition number (p) is an integer of 2 to 300. * is bonding locations)

If above Formula (A-2) is replaced with General Formula (1), X and Y in General Formula (1) become the following structures.

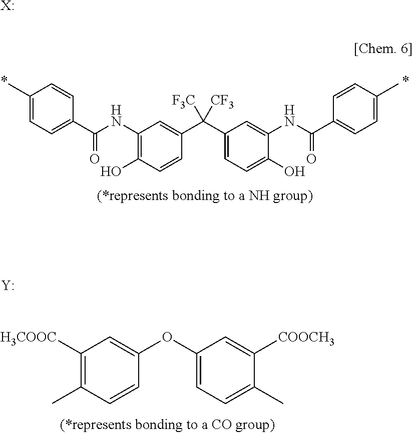

### Example 6

0.15 parts by weight of Surfactant A (Megaface F477, manufactured by DIC Corporation) and 15 parts by weight of γ-butyrolactone were stirred for 1 hour at 300 rpm in a stirrer with stirring blades, and the Surfactant A was dispersed in the γ-butyrolactone. Next, after a mixture of 100 parts by weight of the alkali-soluble resin of following Formula (A-1), 15 parts by weight of the photoacid generator of following Formula (B-1) and 135 parts by weight of γ-butyrolactone was added thereto, the mixture was stirred further for 1 hour or more, and a photosensitive resin composition was obtained.

After the filtrate of the positive-type photosensitive resin composition obtained was coated on a wafer using a spin coater, it was dried for 4 minutes at 120° C. using a hot plate, and a coated film with a thickness of approximately 7 μm was obtained.

The number of particles in the liquid with a diameter of 0.15 μm or more, cissing, and coating properties were evaluated in the same manner as that of Example 1. The evaluation results are shown in Table 1. In Example 6, the number of particles in the liquid was greater than 500/mL. In addition, the cissing of the coated film was 50 pcs or less. The film-coating properties of Example 6 were more favorable than those of Comparative Example 1 and Comparative Example 2, however, poorer than those of Example 4.

### Example 7

0.15 parts by weight of Surfactant A (Megaface F477, manufactured by DIC Corporation) and 150 parts by weight of γ-butyrolactone were stirred for 1 hour at 300 rpm in a stirrer with stirring blades, and a dispersion liquid was obtained by dispersing the Surfactant A in the γ-butyrolactone (the first step). Next, after 100 parts by weight of the alkali-soluble resin of above Formula (A-1), parts by weight of the photoacid generator of above Formula (B-1), and 8 g of a silane compound represented by following Formula (C-1) were sequentially added to the dispersion liquid, the mixture was stirred further for 1 hour or more, and a photosensitive resin composition was obtained (the second step). After the filtrate of the positive-type photosensitive resin composition obtained was coated on a wafer using a spin coater, it was dried for 4 minutes at 120° C. using a hot plate, and a coated film with a thickness of approximately 7 μm was obtained.

The number of particles in the liquid with a diameter of 0.15 μm or more, cissing, and coating properties were evaluated in the same manner as that of Example 1. The evaluation results are shown in Table 1. In Example 6, the number of particles in the liquid was 500/mL or less. In addition, the cissing of the coated film was 20 pcs or less. Furthermore, the coating properties were favorable.

Formula (C-1) is as follows.

CH₂═C(CH₃)COO(CH₂)₃—Si(OCH₃)₃ (C-1)

### Comparative Example 1

After 0.15 parts by weight of Surfactant A (Megaface F477, manufactured by DIC Corporation), 150 parts by weight of γ-butyrolactone, 100 parts by weight of the alkali-soluble resin of Formula (A-1), and 15 parts by weight of the photoacid generator of Formula (B-1) were added at the same time, the mixture was stirred for 1 hour or more, and a photosensitive resin composition was obtained.

After the filtrate of the positive-type photosensitive resin composition obtained was coated on a wafer using a spin coater, it was dried for 4 minutes at 120° C. using a hot plate, and a coated film with a thickness of approximately 7 μm was obtained.

Cissing was evaluated in the same manner as that of Example 1. The evaluation results are shown in Table 1. Evaluation of the number of particles in the liquid with a diameter of 0.15 μm or more was not performed since all the components were added at the same time. In addition, 80 pcs or more cissing of the coated film were detected. In Comparative Example 1, the film-coating properties were poor.

### Comparative Example 2

100 parts by weight of the alkali-soluble resin of Formula (A-1), 15 parts by weight of the photoacid generator of Formula (B-1), and 150 parts by weight of γ-butyrolactone were mixed for 1 hour. Next, 0.15 parts by weight of Surfactant A (Megaface F477, manufactured by DIC Corporation) was added thereto, and then the mixture was stirred further for 1 hour or more, resulting in a photosensitive resin composition.

After the filtrate of the positive-type photosensitive resin composition obtained was coated on a wafer using a spin coater, it was dried for 4 minutes at 120° C. using a hot plate, and a coated film with a thickness of approximately 7 μm was obtained.

Cissing was evaluated in the same manner as that of Example 1. The evaluation results are shown in Table 1. Evaluation of the number of particles in the liquid with a diameter of 0.15 μm or more was not performed since the surfactant was added after the alkali-soluble resin of Formula (A-1) and the photoacid generator of Formula (B-1) were added. In addition, 80 pcs or more of cissing of the coated film were detected. In Comparative Example 2, the film-coating properties were poor.

TABLE 1

| | | Dispersion Conditions and | | | | |
|---|---|---|---|---|---|---|
| | | Degree of Dispersion of C + D | | | | |
| | | Stirring | | | | |
| | | Concentration | Stirring | Degree of Dispersion | Number of Cissing | Coating Property |
| | Blending Order | (ppm) | Time | (Numbers/mL) | Defects (pcs) | Evaluation |
| Example 1 | (C + D)→(A + B) | 1000 | 1 Hour | 330 | 3 | Favorable |
| Example 2 | (C + D)→(A + B) | 1000 | 1 Hour | 250 | 1 | Favorable |
| Example 3 | (C + D)→(A + B) | 1000 | 2 Hours | 220 | 0 | Favorable |
| Example 4 | (C + D)→A + B + D | 3000 | 1 Hour | 450 | 12 | Favorable |
| Example 5 | (C + D)→(A + B) | 1000 | 1 Hour | 300 | 6 | Favorable |
| Example 6 | (C + D)→A + B + D | 9900 | 1 Hour | 780 | 40 | Slightly |
| | | | | | | Favorable |
| Example 7 | (C + D)→A + B + D + E | 1000 | 1 Hour | 330 | 3 | Favorable |

| | | | | |
|---|---|---|---|---|
| Comparative | A + B + C + D | (Evaluation was not performed due to a different | 80 | Poor |
| Example 1 | | dispersion order) | | |
| Comparative | (A + B + D)→C | (Evaluation was not performed due to a different | 96 | Poor |
| Example 2 | | dispersion order) | | |

A: Alkali-soluble resin
B: Photoacid generator
C: Perfluoroalkyl group-containing surfactant
D: Solvent
E: Silane compound

Priority is claimed on Japanese Patent Application No. 2010-127379, filed on Jun. 3, 2010, the content of which is incorporated herein by reference.

1. A method for preparing a photosensitive resin composition including at least (A) an alkali-soluble resin, (B) a photoacid generator, (C) a surfactant, and (D) an organic solvent, said method comprising:
a step of obtaining a dispersion liquid which contains (C) the surfactant and (D) the organic solvent, and does not contain (A) the alkali-soluble resin and (B) the photoacid generator; and
a step of adding (A) the alkali-soluble resin and (B) the photoacid generator to said dispersion liquid.

2. The method for preparing the photosensitive resin composition according to claim 1,
wherein, in said step of obtaining said dispersion liquid, the concentration of (C) the surfactant in said dispersion liquid of (C) the surfactant is less than or equal to a critical micelle concentration.

3. The method for preparing the photosensitive resin composition according to claim 1,
wherein, in said step of obtaining said dispersion liquid, the number of particles with a diameter of 0.15 μm or more is less than or equal to 500/mL.

4. The method for preparing the photosensitive resin composition according to claim 1,
wherein, in said step of obtaining said dispersion liquid, the content of (C) the surfactant with regard to (D) the organic solvent is greater than or equal to 0.005% by mass and less than or equal to 0.5% by mass.

5. The method for preparing the photosensitive resin composition according to claim 1,
wherein, in said step of adding (A) the alkali-soluble resin and (B) the photoacid generator, (D) the organic solvent is further added to said dispersion liquid.

6. The method for preparing the photosensitive resin composition according to claim 1,
wherein (C) the surfactant has a perfluoroalkyl group.

7. The method for preparing the photosensitive resin composition according to claim 1,
wherein (A) the alkali-soluble resin has at least a structure represented by following General Formula (1), 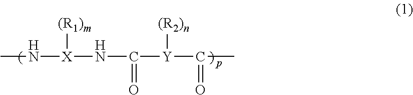
wherein X represents an organic group having a cyclic structure,
R₁ is a hydroxyl group or a —O—R₃,
m is an integer of 0 to 2 and these may be the same as or different from each other,
Y represents an organic group having a cyclic structure,
R₂ is a hydroxyl group, a carboxyl group, a —O—R₃, or a —COO—R₃,
n is an integer of 0 to 4 and these may be the same as or different from each other, here,
R₃ is an organic group having 1 to 15 carbon atoms, however, at least one of R₂ should be a carboxyl group when there are no hydroxyl groups as R₁, and in addition, at least one of R₁ should be a hydroxyl group when there are no carboxyl groups as R₂,
p is an integer of 2 to 300, here, an organic group having a cyclic structure is, for example, an organic group having an aromatic ring such as a benzene ring, or a naphthalene ring, or an organic group having a heterocyclic ring such as a bisphenol ring, a pyrrole ring or a furan ring.

8. A photosensitive resin composition obtained using the method for preparing the photosensitive resin composition according to claim 1.

9. The photosensitive resin composition according to claim 8,
wherein the number of defects occurring when said photosensitive resin composition is coated on the wafer measured under the following conditions is 50 pcs or less,
<Condition>
after said photosensitive resin composition is coated on a 6 inch silicon wafer and dried for 4 minutes at 120° C., cissing is observed by microscopy and the number of defects due to cissing per five sheets of wafers is measured.
